(19) United States
(12) Patent Application Publication
(10) Pub. No.: US 2022/0037285 A1
(43) Pub. Date: Feb. 3, 2022

(54) MULTI-CHIP PACKAGE

(71) Applicant: Samsung Electronics Co., Ltd., Suwon-si (KR)

(72) Inventor: Hyunjun NOH, Cheonan-si (KR)

(73) Assignee: Samsung Electronics Co., Ltd., Suwon-si (KR)

(21) Appl. No.: 17/182,296

(22) Filed: Feb. 23, 2021

(30) Foreign Application Priority Data
Jul. 30, 2020 (KR) 10-2020-0095094

(51) Int. Cl. H01L 25/065; H01L 23/00; H01L 23/31

(52) U.S. Cl. CPC H01L 25/0652; H01L 24/04; H01L 24/48; H01L 23/3121; H01L 24/49; H01L 2224/49111; H01L 2224/04042; H01L 2224/48145; H01L 2224/48225; H01L 2224/49105; H01L 2224/06102

(57) ABSTRACT

A multi-chip package may include a package substrate including a first substrate pad and a second substrate pad, first semiconductor chips stacked on the package substrate in a steplike shape along a first direction, second semiconductor chips stacked on the first semiconductor chips in a steplike shape along a second direction opposite the first direction, first pad wires electrically connecting first bonding pads of the first semiconductor chips with each other, second pad wires electrically connecting second bonding pads of the second semiconductor chips with each other, a first substrate wire electrically connecting the first substrate pad with a first bonding pad of any one among the first semiconductor chips except for a lowermost first semiconductor chip, and a second substrate wire electrically connecting the second substrate pad with a second bonding pad of any one among the second semiconductor chips except for a lowermost second semiconductor chip.

### CROSS-RELATED APPLICATION

This application claims priority under 35 USC § 119 to Korean Patent Application No. 10-2020-0095094, filed on Jul. 30, 2020 in the Korean Intellectual Property Office (KIPO), the contents of which are herein incorporated by reference in their entirety.

### BACKGROUND

### 1. Field

Example embodiments relate to a multi-chip package. More particularly, example embodiments relate to a multi-chip package including a plurality of semiconductor chips stacked in a steplike shape.

### 2. Description of Related Art

Generally, a multi-chip package may include a package substrate, a plurality of semiconductor chips and conductive wires. The semiconductor chips may be stacked on an upper surface of the package substrate in a steplike shape to expose a bonding pad of each of the semiconductor chips. The conductive wires may be electrically connected between the bonding pads of the semiconductor chips. Further, the conductive wires may be electrically connected between the bonding pad of any one of the semiconductor chips and a substrate pad of the package substrate.

According to related arts, the bonding pad of a lowermost semiconductor chip among the semiconductor chips may be electrically connected with the package substrate via the conductive wire. In order to limit and/or prevent a short between the conductive wires, a horizontal length between the lowermost semiconductor chip and the substrate pad may be so long. Thus, the multi-chip package may have a large size.

Further, when other semiconductor chips may be stacked on the stacked semiconductor chips in a steplike shape, the conductive wire may be electrically connected between a bonding pad of an overhang semiconductor chip, which may correspond to a lowermost semiconductor chip among other semiconductor chips, and the substrate pad of the package substrate. In order to accurately bond the conductive wire to the substrate pad of the package substrate, a horizontal length between the overhang semiconductor chip and the substrate pad may be so long. Therefore, the size of the multi-chip package may be more increased.

### SUMMARY

Example embodiments provide a multi-chip package having a small size.

According to an example embodiment, a multi-chip package may include a package substrate including a first substrate pad and a second substrate pad; a first group of semiconductor chips including G1-1 to G1-4 semiconductor chips stacked on an upper surface of the package substrate in a steplike shape along a first direction, the first group of semiconductor chips including G1-1 to G1-4 bonding pads on upper surfaces of the G1-1 to G1-4 semiconductor chips, respectively, and a horizontal length between the first substrate pad and the G1-2 bonding pad being no more than a vertical length between the upper surface of the package substrate and an upper surface of the G1-2 semiconductor chip; a second group of semiconductor chips including G2-1 to G2-4 semiconductor chips stacked on an upper surface of the first group of the semiconductor chips in a steplike shape along a second direction opposite to the first direction, the second group of semiconductor chips including G2-1 to G2-4 bonding pads on upper surfaces of the G2-1 to G2-4 semiconductor chips, respectively, and a horizontal length between the second substrate pad and the G2-2 bonding pad being no more than a vertical length between the upper surface of the package substrate and an upper surface of the G2-2 semiconductor chip; a G1-1 pad wire electrically connecting the G1-1 bonding pad with the G1-2 bonding pad; a G1-2 pad wire electrically connecting the G1-2 bonding pad with the G1-3 bonding pad; a G1-3 pad wire electrically connecting the G1-3 bonding pad with the G1-4 bonding pad; a first substrate wire electrically connecting the G1-2 bonding pad with the first substrate pad; a G2-1 pad wire electrically connecting the G2-1 bonding pad with the G2-2 bonding pad; a G2-2 pad wire electrically connecting the G2-2 bonding pad with the G2-3 bonding pad; a G2-3 pad wire electrically connecting the G2-3 bonding pad with the G2-4 bonding pad; a second substrate wire electrically connecting the G2-2 bonding pad with the second substrate pad; and a molding member on the upper surface of the package substrate, the molding member covering the first group of semiconductor chips and the second group of the semiconductor chips.

According to an example embodiment, a multi-chip package may include a package substrate including a first substrate pad and a second substrate pad; a first group of semiconductor chips including a plurality of first semiconductor chips stacked on an upper surface of the package substrate in a steplike shape along a first direction, the first group of semiconductor chips including first bonding pads on upper surfaces of the plurality of first semiconductor chips, respectively; a second group of semiconductor chips including a plurality of second semiconductor chips stacked on an upper surface of the first group of semiconductor chips in a steplike shape along a second direction opposite to the first direction, the second group of semiconductor chips including second bonding pads on upper surfaces of the plurality of second semiconductor chips, respectively; a first group of pad wires electrically connecting the first bonding pads of the first group of semiconductor chips with each other; a first substrate wire electrically connecting the first substrate pad with a first bonding pad of the first semiconductor chip secondarily positioned from below among the plurality of first semiconductor chips in the first group; a second group of pad wires electrically connecting the second bonding pads of the second group of semiconductor chips with each other; and a second substrate wire electrically connecting the second substrate pad with a second bonding pad of a second semiconductor chip secondarily positioned from below among the plurality of second semiconductor chips in the second group.

According to an example embodiment, a multi-chip package may include a package substrate including a first substrate pad and a second substrate pad; a first group of semiconductor chips including a plurality of first semiconductor chips stacked on an upper surface of the package substrate in a steplike shape along a first direction, the first group of semiconductor chips including first bonding pads on upper surfaces of the plurality of first semiconductor chips, respectively; a first group of pad wires electrically connecting the first bonding pads of the first group of semiconductor chips with each other; and a first substrate wire electrically connecting the first substrate pad with a first bonding pad of any one among the plurality of first semiconductor chips except for a lowermost first semiconductor chip among the plurality of first semiconductor chips in the first group.

According to an example embodiment, the substrate wire may electrically connect the substrate pad of the package substrate with the bonding pad of any one among the semiconductor chips except for the lowermost semiconductor chip. Thus, a sufficient wire gap may be secured between the pad wire and the substrate wire to provide the short horizontal length between the lowermost semiconductor chip and the substrate pad. As a result, the multi-chip package may have a small size.

Further, when the at least two groups of the semiconductor chips may be stacked in the opposite directions, the substrate wire may electrically connect the substrate pad of the package substrate with the bonding pad of the any one on an overhang semiconductor chip corresponding to the lowermost semiconductor chip. Thus, the semiconductor chip over the lowermost semiconductor chip may be electrically connected with the substrate pad of the package substrate via the substrate wire. Although the short horizontal length may be set between the overhang semiconductor chip and the substrate pad, the substrate wire may be accurately bonded to the substrate pad. As a result, the horizontal length between the overhang semiconductor chip and the substrate pad may be more decreased so that the size of the multi-chip package may be more decreased.

### BRIEF DESCRIPTION OF THE DRAWINGS

Example embodiments will be more clearly understood from the following detailed description taken in conjunction with the accompanying drawings. The drawings are not necessarily to scale, emphasis instead being placed upon illustrating principles of inventive concepts. FIGS. 1 to 14 represent non-limiting, example embodiments as described herein.

FIG. 1 is a cross-sectional view illustrating a multi-chip package in accordance with example embodiments;

FIGS. 2 to 7 are cross-sectional views illustrating a method of manufacturing the multi-chip package in FIG. 1;

FIG. 8 is a cross-sectional view illustrating a multi-chip package in accordance with example embodiments;

FIG. 9 is a cross-sectional view illustrating a multi-chip package in accordance with example embodiments;

FIG. 10 is a cross-sectional view illustrating a multi-chip package in accordance with example embodiments;

FIG. 11 is a cross-sectional view illustrating a multi-chip package in accordance with example embodiments;

FIG. 12 is a cross-sectional view illustrating a multi-chip package in accordance with example embodiments;

FIG. 13 is a cross-sectional view illustrating a multi-chip package in accordance with example embodiments; and

FIG. 14 is a cross-sectional view illustrating a multi-chip package in accordance with example embodiments.

### DETAILED DESCRIPTION OF THE EMBODIMENTS

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, example embodiments will be explained in detail with reference to the accompanying drawings.

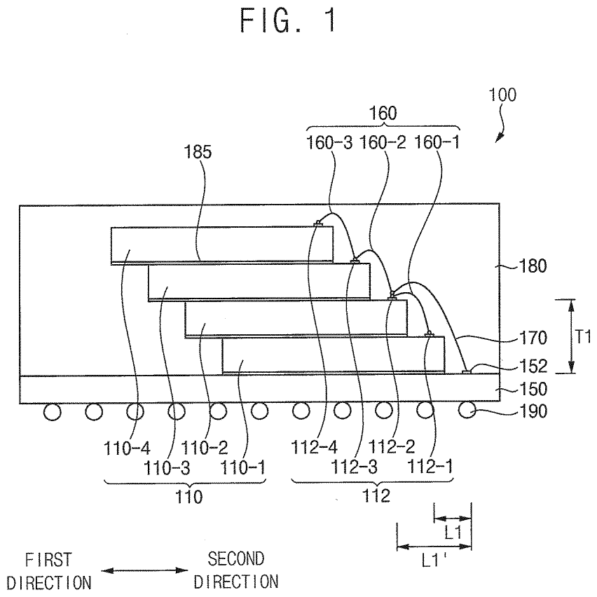

FIG. 1 is a cross-sectional view illustrating a multi-chip package in accordance with example embodiments.

Referring to FIG. 1, a multi-chip package 100 of example embodiments may include a package substrate 150, a first group of semiconductor chips 110, a first group of pad wires 160, a first substrate wire 170, a molding member 180 and external terminals 190.

The package substrate 150 may include an insulation substrate, upper pads arranged on an upper surface of the insulation substrate, lower pads arranged on a lower surface of the insulation substrate, and conductive patterns formed in the insulation substrate to electrically connect the upper pads with the lower pads. In example embodiments, in order to distinguish the upper pads from a bonding pad of a semiconductor chip, a part of the upper pads may be referred to as a first substrate pad 152.

The external terminals 190 may be mounted on the lower pads arranged on the lower surface of the package substrate 150. The external terminals 190 may include solder balls.

In example embodiments, the pad wire may correspond to a wire configured to electrically connect the bonding pads of the semiconductor chips with each other. The substrate wire may correspond to a wire configured to electrically connect the bonding pad of the semiconductor chip with the substrate pad of the package substrate 150.

The first group of the semiconductor chips 110 may be arranged on the upper surface of the package substrate 150. The first group of the semiconductor chips 110 may include a plurality of first semiconductor chips stacked in a steplike shape. The first semiconductor chips may be stacked in the steplike shape along a first direction. Thus, an edge portion of an upper surface of each of the first semiconductor chips may be exposed upwardly.

In example embodiments, the first group of the semiconductor chips 110 may include a 1-1 semiconductor chip 110-1, a 1-2 semiconductor chip 110-2, a 1-3 semiconductor chip 110-3 and a 1-4 semiconductor chip 110-4. The 1-1 semiconductor chip 110-1, the 1-2 semiconductor chip 110-2, the 1-3 semiconductor chip 110-3 and the 1-4 semiconductor chip 110-4 may have substantially the same thickness. Alternatively, the 1-1 semiconductor chip 110-1, the 1-2 semiconductor chip 110-2, the 1-3 semiconductor chip 110-3 and the 1-4 semiconductor chip 110-4 may have different thicknesses. Further, the first group of the semiconductor chips 110 may include stacked two, three or at least five semiconductor chips.

The 1-1 semiconductor chip 110-1 may include a 1-1 bonding pad 112-1. The 1-1 bonding pad 112-1 may be arranged on an edge portion of an upper surface of the 1-1 semiconductor chip 110-1. The 1-2 semiconductor chip 110-2 may include a 1-2 bonding pad 112-2. The 1-2 bonding pad 112-2 may be arranged on an edge portion of an upper surface of the 1-2 semiconductor chip 110-2. The 1-3 semiconductor chip 110-3 may include a 1-3 bonding pad 112-3. The 1-3 bonding pad 112-3 may be arranged on an edge portion of an upper surface of the 1-3 semiconductor chip 110-3. The 1-4 semiconductor chip 110-4 may include a 1-4 bonding pad 112-4. The 1-4 bonding pad 112-4 may be arranged on an edge portion of an upper surface of the 1-4 semiconductor chip 110-4.

The 1-1 semiconductor chip 110-1 may be arranged on the upper surface of the package substrate 150. The 1-2 semiconductor chip 110-2 may be stacked on the upper surface of the 1-1 semiconductor chip 110-1 in the steplike shape along the first direction. Thus, the 1-1 bonding pad 112-1 may be exposed upwardly. The 1-3 semiconductor chip 110-3 may be stacked on the upper surface of the 1-2 semiconductor chip 110-2 in the steplike shape along the first direction. Thus, the 1-2 bonding pad 112-2 may be exposed upwardly. The 1-4 semiconductor chip 110-4 may be stacked on the upper surface of the 1-3 semiconductor chip 110-3 in the steplike shape along the first direction. Thus, the 1-3 bonding pad 112-3 may be exposed upwardly. The 1-1 to 1-4 semiconductor chips 110-1, 110-2, 110-3 and 110-4 may be attached to each other using a die attach film (DAF) 185.

The first group of the pad wires 160 may be configured to electrically connect the 1-1 semiconductor chip 110-1, the 1-2 semiconductor chip 110-2, the 1-3 semiconductor chip 110-3 and the 1-4 semiconductor chip 110-4 with each other. The first group of the pad wires 160 may include a 1-1 pad wire 160-1, a 1-2 pad wire 160-2 and a 1-3 pad wire 160-3. The 1-1 pad wire 160-1 may be configured to electrically connect the 1-1 bonding pad 112-1 with the 1-2 bonding pad 112-2. The 1-2 pad wire 160-2 may be configured to electrically connect the 1-2 bonding pad 112-2 with the 1-3 bonding pad 112-3. The 1-3 pad wire 160-3 may be configured to electrically connect the 1-3 bonding pad 112-3 with the 1-4 bonding pad 112-4.

The first substrate wire 170 may electrically connect the 1-2 bonding pad 112-2 with the first substrate pad 152. In example embodiments, the first substrate wire 170 may not connect the 1-1 bonding pad 112-1 of the 1-1 semiconductor chip 110-1, which may correspond to a lowermost semiconductor chip of the first group of the semiconductor chips 110, with the first substrate pad 152. The first substrate wire 170 may connect the 1-2 bonding pad 112-2 of the 1-2 semiconductor chip 110-2 directly on the 1-1 semiconductor chip 110-1 with the first substrate pad 152. That is, the first substrate wire 170 may be configured to electrically connect the package substrate 150 with the 1-2 semiconductor chip 110-2 secondarily positioned in the first group of the semiconductor chips 110 from below.

In order to limit and/or prevent an electrical short between the first substrate wire 170 with other substrate wires, a horizontal length between a bonding pad and the first substrate pad 152, which may be electrically connected with each other via the first substrate wire 170, may be no more than a vertical length from the upper surface of the package substrate 150 to the bonding pad to which the first substrate wire 170.

According to conventional arts, the first substrate wire 170 may be connected to the 1-1 bonding pad 112-1 of the 1-1 semiconductor chip 110-1 corresponding to the lowermost semiconductor chip. Thus, the horizontal length L1 between the 1-1 bonding pad 112-1 and the first substrate pad 152 may be the vertical length from the upper surface of the package substrate 150 to the upper surface of the 1-1 semiconductor chip 110-1, e.g., a thickness of the 1-1 semiconductor chip 110-1. Therefore, in order to limit and/or prevent the electrical short between the first substrate wire 170 with other substrate wires, it may be required to set a long horizontal length between a side surface of the 1-1 semiconductor chip 110-1 corresponding to the lowermost semiconductor chip and the first substrate pad 152. As a result, this may cause increasing of the package substrate 150 in a size so that the multi-chip package may have a large size.

In contrast, according to example embodiments, as mentioned above, the first substrate wire 170 may connect the 1-2 bonding pad 112-2 of the 1-2 semiconductor chip 110-2 directly on the lowermost semiconductor chip with the first substrate pad 152. Thus, a horizontal length L1′ between the 1-2 bonding pad 112-2 and the first substrate pad 152 may be a vertical length T1 from the upper surface of the package substrate 150 to the upper surface of the 1-2 semiconductor chip 110-2. That is, the horizontal length L1′ between the 1-2 bonding pad 112-2 and the first substrate pad 152 may be a summed thickness of the thickness of the 1-1 semiconductor chip 110-1 and a thickness of the 1-2 semiconductor chip 110-2. Although the horizontal length L1′ between the 1-2 bonding pad 112-2 and the first substrate pad 152 may include the thickness of the 1-2 semiconductor chip 110-2, a measurement point of the horizontal length L1′ between the 1-2 bonding pad 112-2 and the first substrate pad 152 may be the 1-2 bonding pad 112-2 inside the 1-1 bonding pad 112-1 oriented toward a central portion of the package substrate 150 so that the first substrate pad 152 may also be arranged at an inward position toward the central portion of the package substrate 150. Therefore, the horizontal length L1′ between the 1-2 bonding pad 112-2 and the first substrate pad 152 may be decreased so that a horizontal length L1 between the side surface of the 1-1 semiconductor chip 110-1 and the first substrate pad 152 may also be reduced. As a result, the size of the package substrate 150 may be decreased so that the multi-chip package 100 may have a small size.

In example embodiments, the horizontal length L1′ between the 1-2 bonding pad 112-2 and the first substrate pad 152 may be substantially equal to the vertical length T1 from the upper surface of the package substrate 150 to the upper surface of the 1-2 semiconductor chip 110-2. Alternatively, the horizontal length L1′ between the 1-2 bonding pad 112-2 and the first substrate pad 152 may be no more than the vertical length T1 from the upper surface of the package substrate 150 to the upper surface of the 1-2 semiconductor chip 110-2.

Alternatively, in some embodiments, the horizontal length L1′ between the 1-2 bonding pad 112-2 and the first substrate pad 152 may be greater than or equal to the vertical length T1 from the upper surface of the package substrate 150 to the upper surface of the 1-2 semiconductor chip 110-2.

The molding member 180 may be formed on the upper surface of the package substrate 150 to cover the first group of the semiconductor chips 110, the first group of the pad wires 160 and the first substrate wire 170. The molding member 180 may include an epoxy molding compound (EMC).

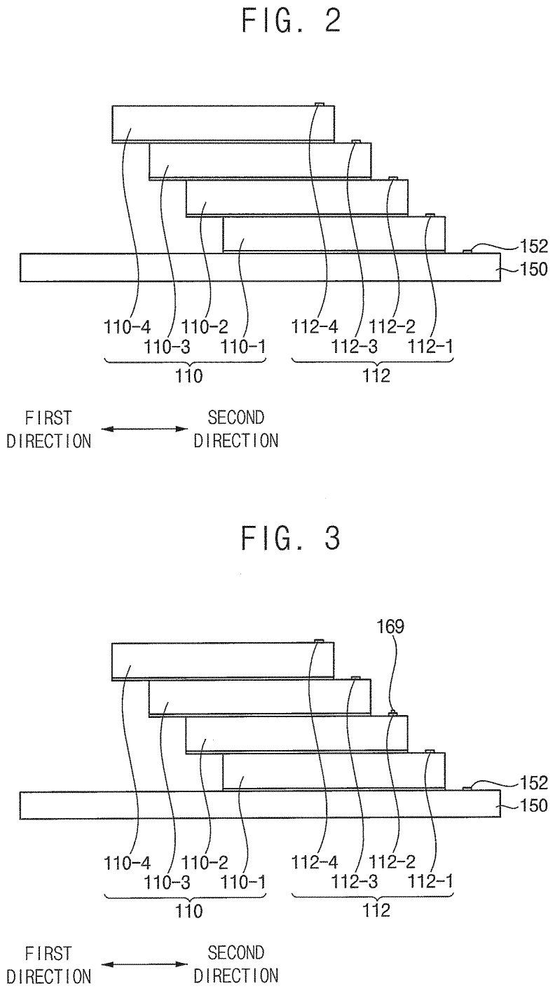

FIGS. 2 to 7 are cross-sectional views illustrating a method of manufacturing the multi-chip package in FIG. 1.

Referring to FIG. 2, the first group of the semiconductor chips 110 may be arranged on the upper surface of the package substrate 150. Particularly, the 1-1 semiconductor chip 110-1 may be attached to the upper surface of the package substrate 150. The 1-2 semiconductor chip 110-2 may be stacked on the upper surface of the 1-1 semiconductor chip 110-1 in the steplike shape along the first direction. Thus, the 1-1 bonding pad 112-1 may be exposed upwardly. The 1-3 semiconductor chip 110-3 may be stacked on the upper surface of the 1-2 semiconductor chip 110-2 in the steplike shape along the first direction. Thus, the 1-2 bonding pad 112-2 may be exposed upwardly. The 1-4 semiconductor chip 110-4 may be stacked on the upper surface of the 1-3 semiconductor chip 110-3 in the steplike shape along the first direction. Thus, the 1-3 bonding pad 112-3 may be exposed upwardly.

Referring to FIG. 3, a ball 169 may be formed on the 1-2 bonding pad 112-2.

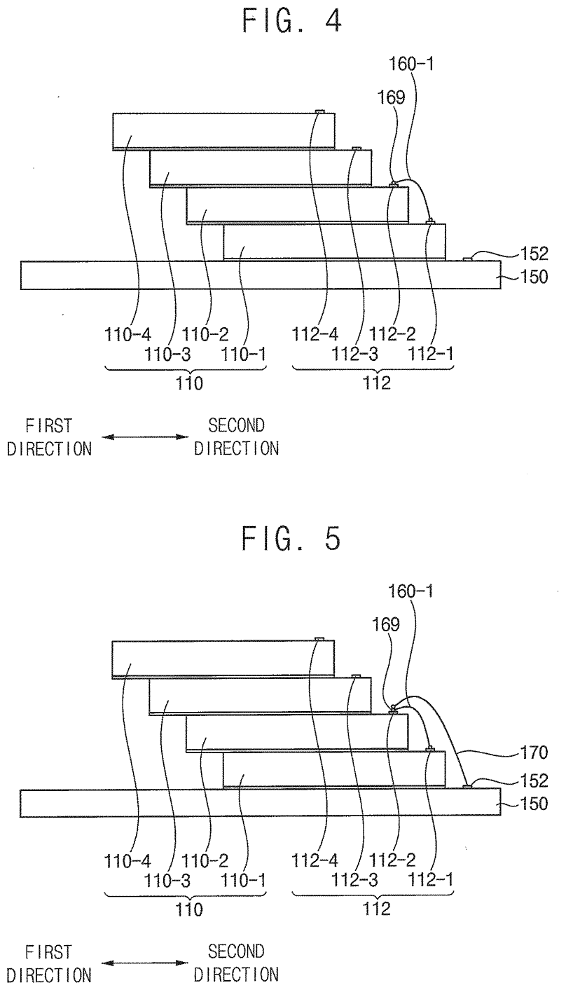

Referring to FIG. 4, the 1-1 pad wire 160-1 may be drawn from the 1-1 bonding pad 112-1 to the ball 169 on the 1-2 bonding pad 112-2. Thus, the 1-1 bonding pad 112-1 and the 1-2 bonding pad 112-2 may be electrically connected with each other via the 1-1 pad wire 160-1.

Referring to FIG. 5, the first substrate wire 170 may be drawn from the ball 169 on the 1-2 bonding pad 112-2 to the first substrate pad 152. Thus, the 1-2 bonding pad 112-2 and the first substrate pad 152 may be electrically connected with each other via the first substrate wire 170.

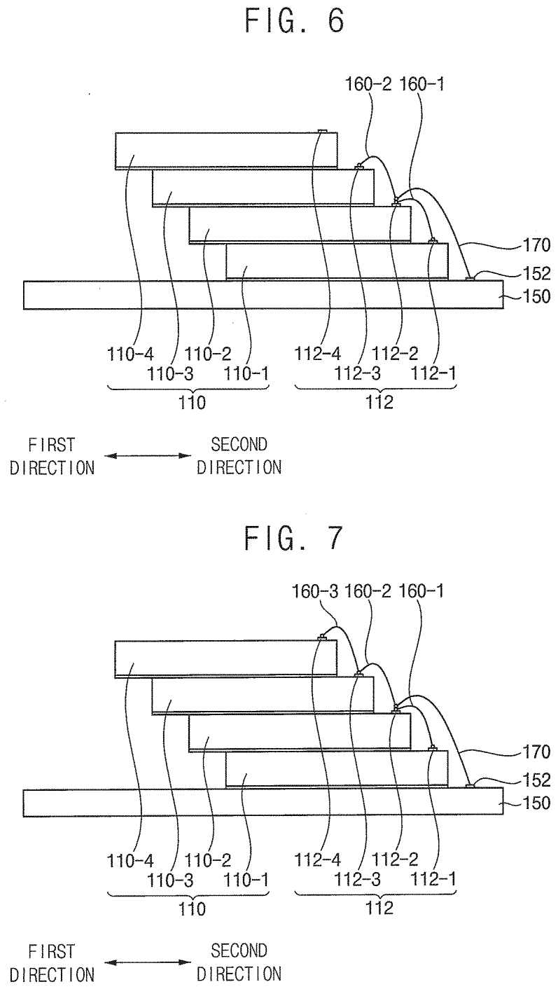

Referring to FIG. 6, the 1-2 pad wire 160-2 may be drawn from the 1-3 bonding pad 112-3 to the 1-2 bonding pad 112-2. Thus, the 1-2 bonding pad 112-2 and the 1-3 bonding pad 112-3 may be electrically connected with each other via the 1-2 pad wire 160-2.

Referring to FIG. 7, the 1-3 pad wire 160-3 may be drawn from the 1-4 bonding pad 112-4 to the 1-3 bonding pad 112-3. Thus, the 1-3 bonding pad 112-3 and the 1-4 bonding pad 112-4 may be electrically connected with each other via the 1-3 pad wire 160-3.

The molding member 180 may be formed on the upper surface of the package substrate 150 to cover the first group of the semiconductor chip 110, the first group of the pad wires 160 and the first substrate wire 170 with the molding member 180. The external terminals 190 may be mounted on the lower surface of the package substrate 150 to complete the multi-chip package 100 in FIG. 1.

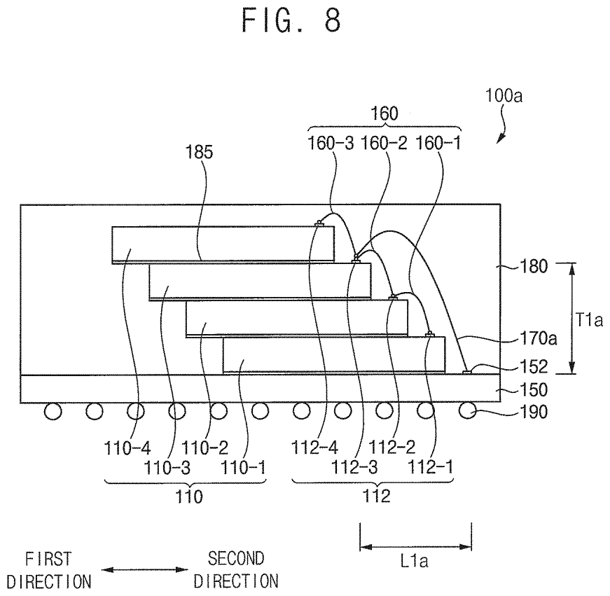

FIG. 8 is a cross-sectional view illustrating a multi-chip package in accordance with example embodiments.

A multi-chip package 100a of example embodiments may include elements substantially the same as those of the multi-chip package 100 in FIG. 1 except for a first substrate wire. Thus, the same reference numerals may refer to the same elements and any further illustrations with respect to the same elements may be omitted herein for brevity.

Referring to FIG. 8, a first substrate wire 170a may be configured to electrically connect the 1-3 bonding pad 112-3 with the first substrate pad 152. That is, the first substrate wire 170a may electrically connect the package substrate 150 with the 1-3 semiconductor chip 110-3 tertiarily positioned in the first group of the semiconductor chips 110 from below.

A horizontal length L1a between the 1-3 bonding pad 112-3 and the first substrate pad 152 may be a vertical length T1a from the upper surface of the package substrate 150 to the upper surface of the 1-3 semiconductor chip 110-3. That is, the horizontal length L1a between the 1-3 bonding pad 112-3 and the first substrate pad 152 may be a summed thickness of the thickness of the 1-1 semiconductor chip 110-1, a thickness of the 1-2 semiconductor chip 110-2 and a thickness of the 1-3 semiconductor chip. A measurement point of the horizontal length L1a between the 1-3 bonding pad 112-3 and the first substrate pad 152 may be the 1-3 bonding pad 112-3 adjacent to the central portion of the package substrate 150 so that the first substrate pad 152 may also be arranged at an inward position toward the central portion of the package substrate 150. Therefore, the horizontal length L1a between the 1-3 bonding pad 112-3 and the first substrate pad 152 may be decreased so that a horizontal length between the side surface of the 1-1 semiconductor chip 110-1 and the first substrate pad 152 may also be reduced. As a result, the size of the package substrate 150 may be decreased so that the multi-chip package 100a may have a small size.

In example embodiments, the horizontal length L1a between the 1-3 bonding pad 112-3 and the first substrate pad 152 may be substantially equal to the vertical length T1a from the upper surface of the package substrate 150 to the upper surface of the 1-3 semiconductor chip 110-3. Alternatively, the horizontal length L1a between the 1-3 bonding pad 112-3 and the first substrate pad 152 may be no more than the vertical length T1a from the upper surface of the package substrate 150 to the upper surface of the 1-3 semiconductor chip 110-3.

Alternatively, in some embodiments, the horizontal length L1a between the 1-3 bonding pad 112-3 and the first substrate pad 152 may be greater than or equal to the vertical length T1a from the upper surface of the package substrate 150 to the upper surface of the 1-3 semiconductor chip 110-3.

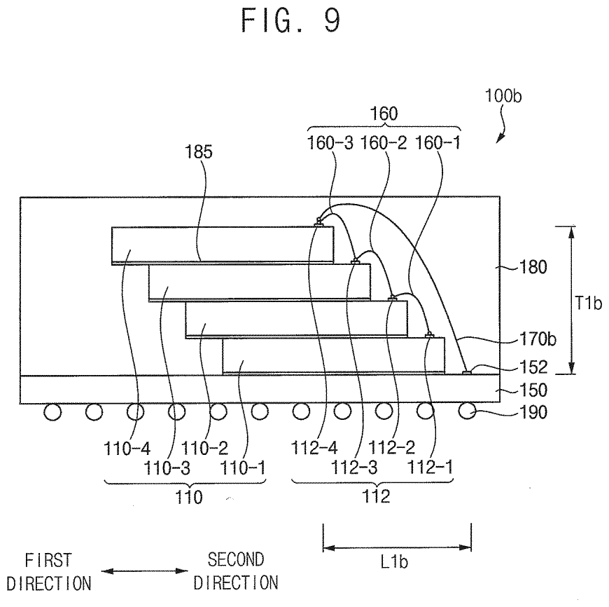

FIG. 9 is a cross-sectional view illustrating a multi-chip package in accordance with example embodiments.

A multi-chip package 100b of example embodiments may include elements substantially the same as those of the multi-chip package 100 in FIG. 1 except for a first substrate wire. Thus, the same reference numerals may refer to the same elements and any further illustrations with respect to the same elements may be omitted herein for brevity.

Referring to FIG. 9, a first substrate wire 170b may be configured to electrically connect the 1-4 bonding pad 112-4 with the first substrate pad 152. That is, the first substrate wire 170b may electrically connect the package substrate 150 with the 1-4 semiconductor chip 110-4 fourthly positioned in the first group of the semiconductor chips 110 from below.

A horizontal length L1b between the 1-4 bonding pad 112-4 and the first substrate pad 152 may be a vertical length T1b from the upper surface of the package substrate 150 to the upper surface of the 1-4 semiconductor chip 110-4. That is, the horizontal length L1b between the 1-4 bonding pad 112-4 and the first substrate pad 152 may be a summed thickness of the thickness of the 1-1 semiconductor chip 110-1, a thickness of the 1-2 semiconductor chip 110-2, a thickness of the 1-3 semiconductor chip and a thickness of the 1-4 semiconductor chip. A measurement point of the horizontal length L1b between the 1-4 bonding pad 112-4 and the first substrate pad 152 may be the 1-4 bonding pad 112-4 more adjacent to the central portion of the package substrate 150 so that the first substrate pad 152 may also be arranged at an inward position toward the central portion of the package substrate 150. Therefore, the horizontal length L1b between the 1-4 bonding pad 112-4 and the first substrate pad 152 may be decreased so that a horizontal length between the side surface of the 1-1 semiconductor chip 110-1 and the first substrate pad 152 may also be reduced. As a result, the size of the package substrate 150 may be decreased so that the multi-chip package 100b may have a small size.

In example embodiments, the horizontal length L1b between the 1-4 bonding pad 112-4 and the first substrate pad 152 may be substantially equal to the vertical length T1b from the upper surface of the package substrate 150 to the upper surface of the 1-4 semiconductor chip 110-4. Alternatively, the horizontal length L1b between the 1-4 bonding pad 112-4 and the first substrate pad 152 may be no more than the vertical length T1b from the upper surface of the package substrate 150 to the upper surface of the 1-4 semiconductor chip 110-4.

Alternatively, in some embodiments, the horizontal length L1b between the 1-4 bonding pad 112-4 and the first substrate pad 152 may be greater than or equal to the vertical length T1b from the upper surface of the package substrate 150 to the upper surface of the 1-4 semiconductor chip 110-4.

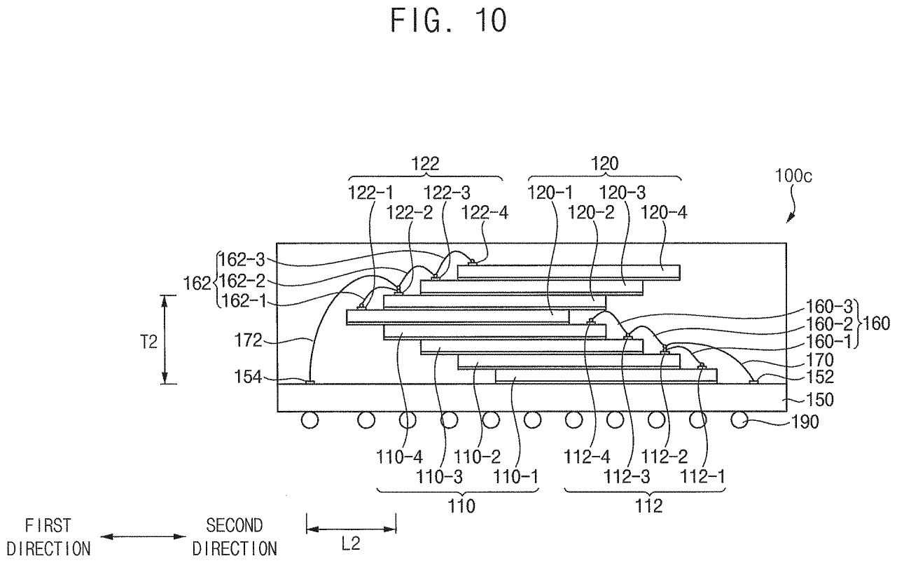

FIG. 10 is a cross-sectional view illustrating a multi-chip package in accordance with example embodiments.

A multi-chip package 100c of example embodiments may include elements substantially the same as those of the multi-chip package 100 in FIG. 1 except for further including a second group of semiconductor chips, a second group of pad wires and a second substrate wire. Thus, the same reference numerals may refer to the same elements and any further illustrations with respect to the same elements may be omitted herein for brevity.

Referring to FIG. 10, the package substrate 150 may further include a second substrate pad 154. The second substrate pad 154 may be placed at a position opposite to the first substrate pad 152.

A second group of the semiconductor chips 120 may be arranged on the upper surface of the first group of the semiconductor chip 110. The second group of the semiconductor chips 120 may include a plurality of second semiconductor chips stacked in a steplike shape. The second semiconductor chips may be stacked in the steplike shape along a second direction opposite to the first direction. Thus, an edge portion of an upper surface of each of the second semiconductor chips may be exposed upwardly.

In example embodiments, the second group of the semiconductor chips 120 may include a 2-1 semiconductor chip 120-1, a 2-2 semiconductor chip 120-2, a 2-3 semiconductor chip 120-3 and a 2-4 semiconductor chip 120-4. The 2-1 semiconductor chip 120-1, the 2-2 semiconductor chip 120-2, the 2-3 semiconductor chip 120-3 and the 2-4 semiconductor chip 120-4 may have substantially the same thickness. Alternatively, the 2-1 semiconductor chip 120-1, the 2-2 semiconductor chip 120-2, the 2-3 semiconductor chip 120-3 and the 2-4 semiconductor chip 120-4 may have different thicknesses. Further, the second group of the semiconductor chips 120 may include stacked two, three or at least five semiconductor chips.

The 2-1 semiconductor chip 120-1 may include a 2-1 bonding pad 122-1. The 2-1 bonding pad 122-1 may be arranged on an edge portion of an upper surface of the 2-1 semiconductor chip 120-1. The 2-2 semiconductor chip 120-2 may include a 2-2 bonding pad 122-2. The 2-2 bonding pad 122-2 may be arranged on an edge portion of an upper surface of the 2-2 semiconductor chip 120-2. The 2-3 semiconductor chip 120-3 may include a 2-3 bonding pad 122-3. The 2-3 bonding pad 122-3 may be arranged on an edge portion of an upper surface of the 2-3 semiconductor chip 120-3. The 2-4 semiconductor chip 120-4 may include a 2-4 bonding pad 122-4. The 2-4 bonding pad 122-4 may be arranged on an edge portion of an upper surface of the 2-4 semiconductor chip 120-4.

The 2-1 semiconductor chip 110-1 may be stacked on the upper surface of the 1-4 semiconductor chip 110-4 in the steplike shape along the first direction. Thus, the 1-4 bonding pad 112-4 may be exposed upwardly. The 2-2 semiconductor chip 120-2 may be stacked on the upper surface of the 2-1 semiconductor chip 120-1 in the steplike shape along the second direction. Thus, the 2-1 bonding pad 122-1 may be exposed upwardly. The 2-3 semiconductor chip 120-3 may be stacked on the upper surface of the 2-2 semiconductor chip 120-2 in the steplike shape along the second direction. Thus, the 2-2 bonding pad 122-2 may be exposed upwardly. The 2-4 semiconductor chip 120-4 may be stacked on the upper surface of the 2-3 semiconductor chip 120-3 in the steplike shape along the second direction. Thus, the 2-3 bonding pad 122-3 may be exposed upwardly. The 2-1 to 2-4 semiconductor chips 120-1, 120-2, 120-3 and 120-4 may be attached to each other using a die attach film (DAF) 185.

A second group of the pad wires 162 may be configured to electrically connect the 2-1 semiconductor chip 120-1, the 2-2 semiconductor chip 120-2, the 2-3 semiconductor chip 120-3 and the 2-4 semiconductor chip 120-4 with each other. The second group of the pad wires 162 may include a 2-1 pad wire 162-1, a 2-2 pad wire 162-2 and a 2-3 pad wire 162-3. The 2-1 pad wire 162-1 may be configured to electrically connect the 2-1 bonding pad 122-1 with the 2-2 bonding pad 122-2. The 2-2 pad wire 162-2 may be configured to electrically connect the 2-2 bonding pad 122-2 with the 2-3 bonding pad 122-3. The 2-3 pad wire 162-3 may be configured to electrically connect the 2-3 bonding pad 122-3 with the 2-4 bonding pad 122-4.

A second substrate wire 172 may electrically connect the 2-2 bonding pad 122-2 with the second substrate pad 154. In example embodiments, the second substrate wire 172 may not connect the 2-1 bonding pad 122-1 of the 2-1 semiconductor chip 120-1, which may correspond to an overhang semiconductor chip of the second group of the semiconductor chips 120, with the second substrate pad 154. The second substrate wire 172 may connect the 2-2 bonding pad 122-2 of the 2-2 semiconductor chip 110-2 directly on the 2-1 semiconductor chip 120-1 with the second substrate pad 154. That is, the second substrate wire 172 may be configured to electrically connect the package substrate 150 with the 2-2 semiconductor chip 120-2 secondarily positioned in the second group of the semiconductor chips 120 from below.

In order to limit and/or prevent an electrical short between the second substrate wire 172 with other substrate wires, a horizontal length a bonding pad and the second substrate pad 154, which may be electrically connected with each other via the second substrate wire 172, may be a vertical length from the upper surface of the package substrate 150 to the bonding pad to which the second substrate wire 172.

According to conventional arts, the second substrate wire 172 may be connected to the 2-1 bonding pad 122-1 of the 2-1 semiconductor chip 120-1 corresponding to the overhang semiconductor chip. Thus, the horizontal length between the 2-1 bonding pad 122-1 and the second substrate pad 154 may be the vertical length from the upper surface of the package substrate 150 to the upper surface of the 2-1 semiconductor chip 120-1. Therefore, in order to limit and/or prevent the electrical short between the second substrate wire 172 with other substrate wires, it may be required to set a long horizontal length between a side surface of the 2-1 semiconductor chip 120-1 corresponding to the overhang semiconductor chip and the second substrate pad 154. As a result, this may cause increasing of the package substrate 150 in a size so that the multi-chip package may have a large size.

In contrast, according to example embodiments, as mentioned above, the second substrate wire 172 may connect the 2-2 bonding pad 122-2 of the 2-2 semiconductor chip 120-2 directly on the overhang semiconductor chip with the second substrate pad 154. Thus, a horizontal length L2 between the 2-2 bonding pad 122-2 and the second substrate pad 154 may be a vertical length T2 from the upper surface of the package substrate 150 to the upper surface of the 2-2 semiconductor chip 120-2. A measurement point of the horizontal length L2 between the 2-2 bonding pad 112-2 and the second substrate pad 154 may be the 2-2 bonding pad 122-2 inside the 2-1 bonding pad 122-1 oriented toward a central portion of the package substrate 150 so that the second substrate pad 154 may also be arranged at an inward position toward the central portion of the package substrate 150. Therefore, the horizontal length L2 between the 2-2 bonding pad 122-2 and the second substrate pad 154 may be decreased so that a horizontal length between the side surface of the 2-1 semiconductor chip 120-1 and the second substrate pad 154 may also be reduced. As a result, the size of the package substrate 150 may be decreased so that the multi-chip package 100c may have a small size.

In example embodiments, the horizontal length L2 between the 2-2 bonding pad 122-2 and the second substrate pad 154 may be substantially equal to the vertical length T2 from the upper surface of the package substrate 150 to the upper surface of the 2-2 semiconductor chip 120-2. Alternatively, the horizontal length L2 between the 2-2 bonding pad 122-2 and the second substrate pad 154 may be no more than the vertical length T2 from the upper surface of the package substrate 150 to the upper surface of the 2-2 semiconductor chip 120-2.

Alternatively, the multi-chip package 100c may include the wire bonding structure in FIG. 8 or the wire bonding structure in FIG. 9.

Alternatively, in some embodiments, the horizontal length L2 between the 2-2 bonding pad 122-2 and the second substrate pad 154 may be greater than or equal to the vertical length T2 from the upper surface of the package substrate 150 to the upper surface of the 2-2 semiconductor chip 120-2.

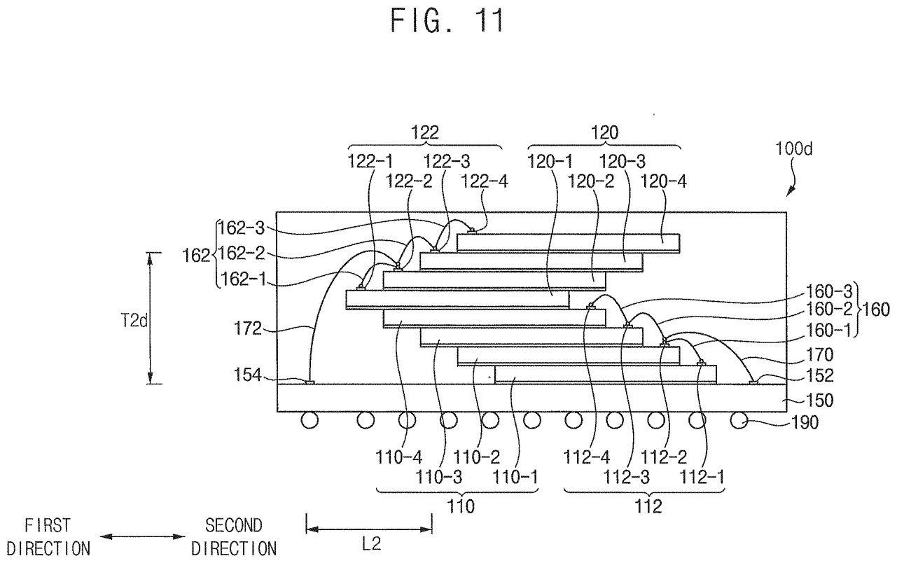

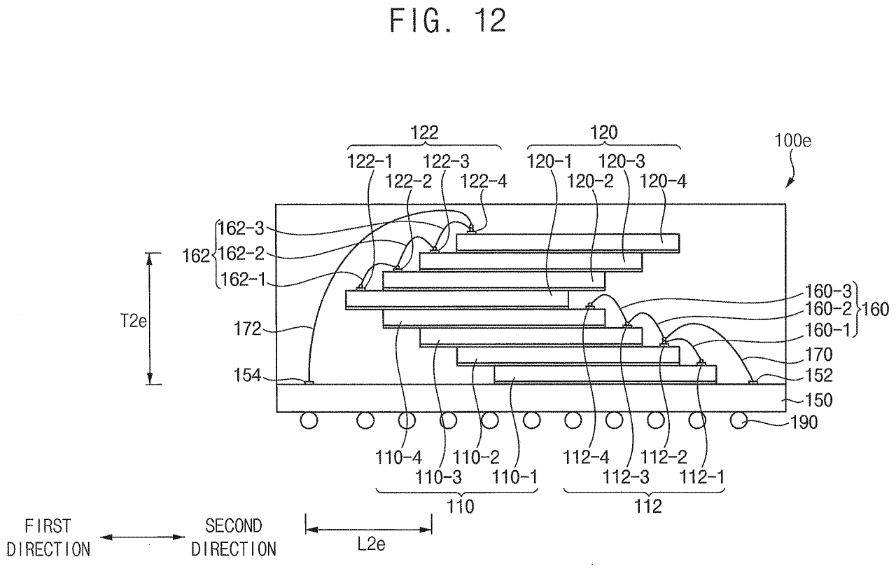

FIG. 11 is a cross-sectional view illustrating a multi-chip package in accordance with example embodiments.

A multi-chip package 100d of example embodiments may include elements substantially the same as those of the multi-chip package 200 in FIG. 10 except for a second substrate wire. Thus, the same reference numerals may refer to the same elements and any further illustrations with respect to the same elements may be omitted herein for brevity.

Referring to FIG. 11, a second substrate wire 170b may be configured to electrically connect the 2-3 bonding pad 122-3 with the second substrate pad 154. That is, the second substrate wire 170b may electrically connect the package substrate 150 with the 2-3 semiconductor chip 120-3 tertiarily positioned in the second group of the semiconductor chips 120 from below.

A horizontal length L2d between the 2-3 bonding pad 122-3 and the second substrate pad 154 may be a vertical length T2d from the upper surface of the package substrate 150 to the upper surface of the 2-3 semiconductor chip 120-3. A measurement point of the horizontal length L2d between the 2-3 bonding pad 122-3 and the second substrate pad 154 may be the 2-3 bonding pad 122-3 adjacent to the central portion of the package substrate 150 so that the second substrate pad 154 may also be arranged at an inward position toward the central portion of the package substrate 150. Therefore, the horizontal length L2d between the 2-3 bonding pad 122-3 and the second substrate pad 154 may be decreased so that a horizontal length between the side surface of the 2-1 semiconductor chip 120-1 and the second substrate pad 154 may also be reduced. As a result, the size of the package substrate 150 may be decreased so that the multi-chip package 100d may have a small size.

In example embodiments, the horizontal length L2d between the 2-3 bonding pad 122-3 and the second substrate pad 154 may be substantially equal to the vertical length T2d from the upper surface of the package substrate 150 to the upper surface of the 2-3 semiconductor chip 120-3. Alternatively, the horizontal length L2d between the 2-3 bonding pad 122-3 and the second substrate pad 154 may be no more than the vertical length T2d from the upper surface of the package substrate 150 to the upper surface of the 2-3 semiconductor chip 120-3.

Alternatively, the multi-chip package 100d may include the wire bonding structure in FIG. 8 or the wire bonding structure in FIG. 9.

Alternatively, in some embodiments, the horizontal length L2d between the 2-3 bonding pad 122-3 and the second substrate pad 154 may be greater than the vertical length T2d from the upper surface of the package substrate 150 to the upper surface of the 2-3 semiconductor chip 120-3.

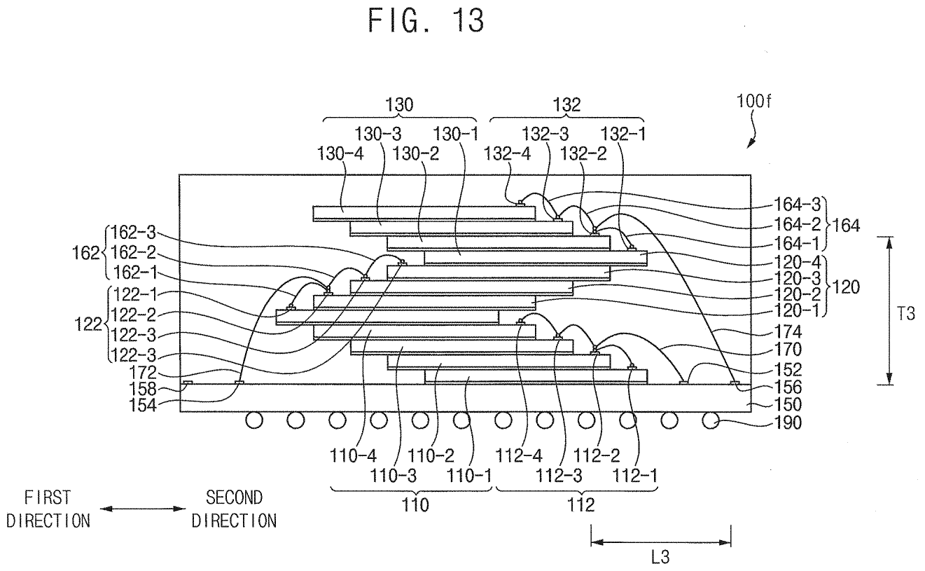

FIG. 12 is a cross-sectional view illustrating a multi-chip package in accordance with example embodiments.

A multi-chip package 100e of example embodiments may include elements substantially the same as those of the multi-chip package 100c in FIG. 10 except for a second substrate wire. Thus, the same reference numerals may refer to the same elements and any further illustrations with respect to the same elements may be omitted herein for brevity.

Referring to FIG. 12, a second substrate wire 170e may be configured to electrically connect the 2-4 bonding pad 122-4 with the second substrate pad 154. That is, the second substrate wire 170e may electrically connect the package substrate 150 with the 2-4 semiconductor chip 120-4 fourthly positioned in the second group of the semiconductor chips 120 from below.

A horizontal length L2e between the 2-4 bonding pad 122-4 and the second substrate pad 154 may be a vertical length T2e from the upper surface of the package substrate 150 to the upper surface of the 2-4 semiconductor chip 120-4. A measurement point of the horizontal length L2e between the 2-4 bonding pad 122-4 and the second substrate pad 154 may be the 2-4 bonding pad 122-4 more adjacent to the central portion of the package substrate 150 so that the second substrate pad 154 may also be arranged at an inward position toward the central portion of the package substrate 150. Therefore, the horizontal length L2e between the 2-4 bonding pad 122-4 and the second substrate pad 154 may be decreased so that a horizontal length between the side surface of the 2-1 semiconductor chip 120-1 and the second substrate pad 154 may also be reduced. As a result, the size of the package substrate 150 may be decreased so that the multi-chip package 100e may have a small size.

In example embodiments, the horizontal length L2e between the 2-4 bonding pad 122-4 and the second substrate pad 154 may be substantially equal to the vertical length T2e from the upper surface of the package substrate 150 to the upper surface of the 2-4 semiconductor chip 120-4. Alternatively, the horizontal length L2e between the 2-4 bonding pad 122-4 and the second substrate pad 154 may be no more than the vertical length T2e from the upper surface of the package substrate 150 to the upper surface of the 2-4 semiconductor chip 120-4.

Alternatively, the multi-chip package 100e may include the wire bonding structure in FIG. 8 or the wire bonding structure in FIG. 9.

Alternatively, in some embodiments, the horizontal length L2e between the 2-4 bonding pad 122-4 and the second substrate pad 154 may be greater than the vertical length T2e from the upper surface of the package substrate 150 to the upper surface of the 2-4 semiconductor chip 120-4.

FIG. 13 is a cross-sectional view illustrating a multi-chip package in accordance with example embodiments.

A multi-chip package 100f of example embodiments may include elements substantially the same as those of the multi-chip package 100c in FIG. 10 except for further including a third group of semiconductor chips, a third group of pad wires and a third substrate wire. Thus, the same reference numerals may refer to the same elements and any further illustrations with respect to the same elements may be omitted herein for brevity.

Referring to FIG. 13, the package substrate 150 may further include a third substrate pad 156. The third substrate pad 156 may be placed at a position outside the first substrate pad 152. For example, compared to the first substrate pad 152, the third substrate pad 156 may be farther from a region of the package substrate 150 (e.g., 1-1 semiconductor chip 110-1) between the first substrate pad 152 and the second substrate pad 154. The third substrate pad 156 may be farther from the second substrate pad 154 than the first substrate pad 152. The third substrate pad 156 may be closer to an edge of the package substrate 150 adjacent thereto compared to a distance between the first substrate pad 152 and the package substrate 150 adjacent thereto.

A third group of the semiconductor chips 130 may be arranged on the upper surface of the second group of the semiconductor chip 120. The third group of the semiconductor chips 130 may include a plurality of third semiconductor chips stacked in a steplike shape. The third semiconductor chips may be stacked in the steplike shape along the first direction. Thus, an edge portion of an upper surface of each of the third semiconductor chips may be exposed upwardly.

In example embodiments, the third group of the semiconductor chips 130 may include a 3-1 semiconductor chip 130-1, a 3-2 semiconductor chip 130-2, a 3-3 semiconductor chip 130-3 and a 3-4 semiconductor chip 130-4. The 3-1 semiconductor chip 130-1, the 3-2 semiconductor chip 130-2, the 3-3 semiconductor chip 130-3 and the 3-4 semiconductor chip 130-4 may have substantially the same thickness. Alternatively, the 3-1 semiconductor chip 130-1, the 3-2 semiconductor chip 130-2, the 3-3 semiconductor chip 130-3 and the 3-4 semiconductor chip 130-4 may have different thicknesses. Further, the third group of the semiconductor chips 130 may include stacked two, three or at least five semiconductor chips.

The 3-1 semiconductor chip 130-1 may include a 3-1 bonding pad 132-1. The 3-1 bonding pad 132-1 may be arranged on an edge portion of an upper surface of the 3-1 semiconductor chip 130-1. The 3-2 semiconductor chip 130-2 may include a 3-2 bonding pad 132-2. The 3-2 bonding pad 132-2 may be arranged on an edge portion of an upper surface of the 3-2 semiconductor chip 130-2. The 3-3 semiconductor chip 130-3 may include a 3-3 bonding pad 132-3. The 3-3 bonding pad 132-3 may be arranged on an edge portion of an upper surface of the 3-3 semiconductor chip 130-3. The 3-4 semiconductor chip 130-4 may include a 3-4 bonding pad 132-4. The 3-4 bonding pad 132-4 may be arranged on an edge portion of an upper surface of the 3-4 semiconductor chip 130-4.

The 3-1 semiconductor chip 130-1 may be stacked on the upper surface of the 2-4 semiconductor chip 120-4 in the steplike shape along the second direction. Thus, the 2-4 bonding pad 122-4 may be exposed upwardly. The 3-2 semiconductor chip 130-2 may be stacked on the upper surface of the 3-1 semiconductor chip 130-1 in the steplike shape along the first direction. Thus, the 3-1 bonding pad 132-1 may be exposed upwardly. The 3-3 semiconductor chip 130-3 may be stacked on the upper surface of the 3-2 semiconductor chip 130-2 in the steplike shape along the first direction. Thus, the 3-2 bonding pad 132-2 may be exposed upwardly. The 3-4 semiconductor chip 130-4 may be stacked on the upper surface of the 3-3 semiconductor chip 130-3 in the steplike shape along the first direction. Thus, the 3-3 bonding pad 132-3 may be exposed upwardly. The 3-1 to 3-4 semiconductor chips 130-1, 130-2, 130-3 and 130-4 may be attached to each other using a die attach film (DAF) 185.

A third group of the pad wires 164 may be configured to electrically connect the 3-1 semiconductor chip 130-1, the 3-2 semiconductor chip 130-2, the 3-3 semiconductor chip 130-3 and the 3-4 semiconductor chip 130-4 with each other. The third group of the pad wires 163 may include a 3-1 pad wire 164-1, a 3-2 pad wire 164-2 and a 3-3 pad wire 164-3. The 3-1 pad wire 164-1 may be configured to electrically connect the 3-1 bonding pad 132-1 with the 3-2 bonding pad 132-2. The 3-2 pad wire 164-2 may be configured to electrically connect the 3-2 bonding pad 132-2 with the 3-3 bonding pad 132-3. The 3-3 pad wire 164-3 may be configured to electrically connect the 3-3 bonding pad 132-3 with the 3-4 bonding pad 132-4.

A third substrate wire 174 may electrically connect the 3-2 bonding pad 132-2 with the third substrate pad 156. In example embodiments, the third substrate wire 174 may connect the 3-2 bonding pad 132-2 of the 3-2 semiconductor chip 130-2 directly on the 3-1 semiconductor chip 130-1 with the third substrate pad 156. That is, the third substrate wire 174 may be configured to electrically connect the package substrate 150 with the 3-2 semiconductor chip 130-2 secondarily positioned in the third group of the semiconductor chips 130 from below. Alternatively, the third substrate wire 174 may connect the 3-3 bonding pad 132-3 or the 3-4 bonding pad 132-4 with the third substrate pad 156.

A horizontal length L3 between the 3-2 bonding pad 132-2 and the third substrate pad 156 may be a vertical length T3 from the upper surface of the package substrate 150 to the upper surface of the 3-2 semiconductor chip 130-2. A measurement point of the horizontal length L3 between the 3-2 bonding pad 132-2 and the third substrate pad 156 may be the 3-2 bonding pad 132-2 inside the 3-1 bonding pad 132-1 oriented toward a central portion of the package substrate 150 so that the third substrate pad 156 may also be arranged at an inward position toward the central portion of the package substrate 150. Therefore, the horizontal length L3 between the 3-2 bonding pad 132-2 and the third substrate pad 154 may be decreased so that a horizontal length between the side surface of the 3-1 semiconductor chip 130-1 and the third substrate pad 154 may also be reduced. As a result, the size of the package substrate 150 may be decreased so that the multi-chip package 100f may have a small size.

In example embodiments, the horizontal length L3 between the 3-2 bonding pad 132-2 and the third substrate pad 156 may be substantially equal to the vertical length T3 from the upper surface of the package substrate 150 to the upper surface of the 3-2 semiconductor chip 130-2. Alternatively, the horizontal length L3 between the 3-2 bonding pad 132-2 and the third substrate pad 156 may be no more than the vertical length T3 from the upper surface of the package substrate 150 to the upper surface of the 3-2 semiconductor chip 130-2.

Alternatively, in some embodiments, the horizontal length L3 between the 3-2 bonding pad 132-2 and the third substrate pad 156 may be greater than the vertical length T3 from the upper surface of the package substrate 150 to the upper surface of the 3-2 semiconductor chip 130-2.

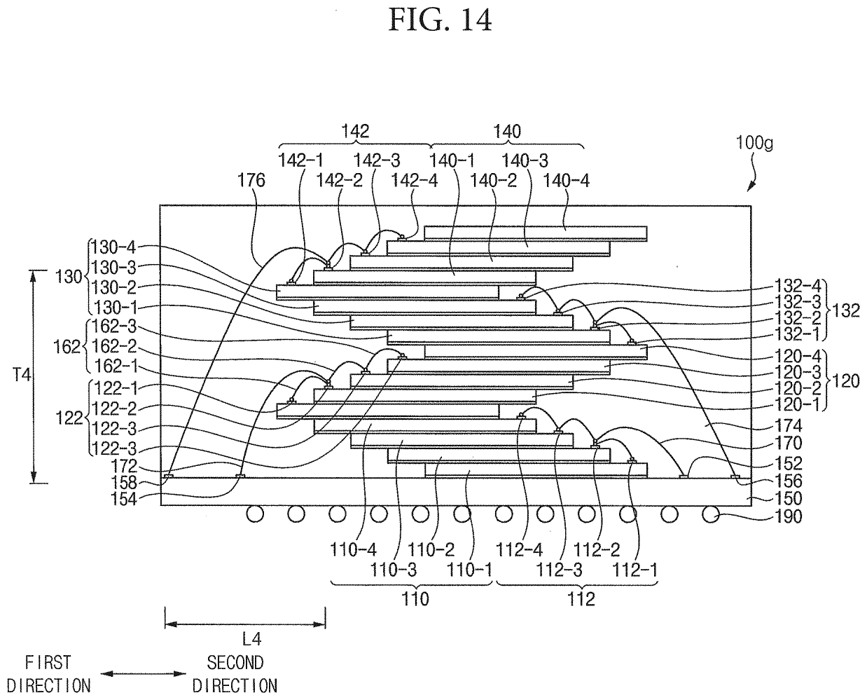

FIG. 14 is a cross-sectional view illustrating a multi-chip package in accordance with example embodiments.

A multi-chip package 100g of example embodiments may include elements substantially the same as those of the multi-chip package 100f in FIG. 13 except for further including a fourth group of semiconductor chips, a fourth group of pad wires and a fourth substrate wire. Thus, the same reference numerals may refer to the same elements and any further illustrations with respect to the same elements may be omitted herein for brevity.

Referring to FIG. 14, the package substrate 150 may further include a fourth substrate pad 158. The fourth substrate pad 158 may be placed at a position outside the second substrate pad 154. For example, compared to the second substrate pad 154, the fourth substrate pad 158 may be farther from a region of the package substrate 150 (e.g., 1-1 semiconductor chip 110-1) between the first substrate pad 152 and the second substrate pad 154. The fourth substrate pad 158 may be farther from the first substrate pad 152 than the second substrate pad 154. The fourth substrate pad 158 may be closer to an edge of the package substrate 150 adjacent thereto compared to a distance between the second substrate pad 154 and the edge of the package substrate 150 adjacent thereto.

A fourth group of the semiconductor chips 140 may be arranged on the upper surface of the third group of the semiconductor chip 130. The fourth group of the semiconductor chips 140 may include a plurality of fourth semiconductor chips stacked in a steplike shape along the second direction. Thus, an edge portion of an upper surface of each of the fourth semiconductor chips may be exposed upwardly.

In example embodiments, the fourth group of the semiconductor chips 140 may include a 4-1 semiconductor chip 140-1, a 4-2 semiconductor chip 140-2, a 4-3 semiconductor chip 140-3 and a 4-4 semiconductor chip 140-4. The 4-1 semiconductor chip 140-1, the 4-2 semiconductor chip 140-2, the 4-3 semiconductor chip 140-3 and the 4-4 semiconductor chip 140-4 may have substantially the same thickness. Alternatively, the 4-1 semiconductor chip 140-1, the 4-2 semiconductor chip 140-2, the 4-3 semiconductor chip 140-3 and the 4-4 semiconductor chip 140-4 may have different thicknesses. Further, the fourth group of the semiconductor chips 140 may include stacked two, three or at least five semiconductor chips.

The 4-1 semiconductor chip 140-1 may include a 4-1 bonding pad 142-1. The 4-1 bonding pad 142-1 may be arranged on an edge portion of an upper surface of the 4-1 semiconductor chip 140-1. The 4-2 semiconductor chip 140-2 may include a 4-2 bonding pad 142-2. The 4-2 bonding pad 142-2 may be arranged on an edge portion of an upper surface of the 4-2 semiconductor chip 140-2. The 4-3 semiconductor chip 140-3 may include a 4-3 bonding pad 142-3. The 4-3 bonding pad 142-3 may be arranged on an edge portion of an upper surface of the 4-3 semiconductor chip 140-3. The 4-4 semiconductor chip 140-4 may include a 4-4 bonding pad 142-4. The 4-4 bonding pad 142-4 may be arranged on an edge portion of an upper surface of the 4-4 semiconductor chip 140-4.

The 4-1 semiconductor chip 140-1 may be stacked on the upper surface of the 3-4 semiconductor chip 130-4 in the steplike shape along the first direction. Thus, the 3-4 bonding pad 132-4 may be exposed upwardly. The 4-2 semiconductor chip 140-2 may be stacked on the upper surface of the 4-1 semiconductor chip 140-1 in the steplike shape along the second direction. Thus, the 4-1 bonding pad 142-1 may be exposed upwardly. The 4-3 semiconductor chip 140-3 may be stacked on the upper surface of the 4-2 semiconductor chip 140-2 in the steplike shape along the second direction. Thus, the 4-2 bonding pad 142-2 may be exposed upwardly. The 4-4 semiconductor chip 140-4 may be stacked on the upper surface of the 4-3 semiconductor chip 140-3 in the steplike shape along the second direction. Thus, the 4-3 bonding pad 142-3 may be exposed upwardly. The 4-1 to 4-4 semiconductor chips 140-1, 140-2, 140-3 and 140-4 may be attached to each other using a die attach film (DAF) 185.

A fourth group of the pad wires 166 may be configured to electrically connect the 4-1 semiconductor chip 140-1, the 4-2 semiconductor chip 140-2, the 4-3 semiconductor chip 140-3 and the 4-4 semiconductor chip 140-4 with each other. The fourth group of the pad wires 166 may include a 4-1 pad wire 166-1, a 4-2 pad wire 166-2 and a 4-3 pad wire 166-3. The 4-1 pad wire 166-1 may be configured to electrically connect the 4-1 bonding pad 142-1 with the 4-2 bonding pad 142-2. The 4-2 pad wire 166-2 may be configured to electrically connect the 4-2 bonding pad 142-2 with the 4-3 bonding pad 142-3. The 4-3 pad wire 166-3 may be configured to electrically connect the 4-3 bonding pad 142-3 with the 4-4 bonding pad 142-4.

A fourth substrate wire 176 may electrically connect the 4-2 bonding pad 142-2 with the fourth substrate pad 158. In example embodiments, the fourth substrate wire 176 may not connect the fourth substrate pad 158 with the 4-1 bonding pad 142-1 of the 4-1 semiconductor chip 140-1 corresponding to the overhang semiconductor chip. The fourth substrate wire 176 may connect the 4-2 bonding pad 134-2 of the 4-2 semiconductor chip 140-2 directly on the 4-1 semiconductor chip 140-1 with the fourth substrate pad 158. That is, the fourth substrate wire 176 may be configured to electrically connect the package substrate 150 with the 4-2 semiconductor chip 140-2 secondarily positioned in the fourth group of the semiconductor chips 140 from below. Alternatively, the fourth substrate wire 176 may connect the 4-3 bonding pad 142-3 or the 4-4 bonding pad 142-4 with the fourth substrate pad 158.

A horizontal length L4 between the 4-2 bonding pad 142-2 and the fourth substrate pad 158 may be a vertical length T4 from the upper surface of the package substrate 150 to the upper surface of the 4-2 semiconductor chip 140-2. A measurement point of the horizontal length L4 between the 4-2 bonding pad 142-2 and the fourth substrate pad 158 may be the 4-2 bonding pad 142-2 inside the 4-1 bonding pad 142-1 oriented toward a central portion of the package substrate 150 so that the fourth substrate pad 158 may also be arranged at an inward position toward the central portion of the package substrate 150. Therefore, the horizontal length L4 between the 4-2 bonding pad 142-2 and the fourth substrate pad 158 may be decreased so that a horizontal length between the side surface of the 4-1 semiconductor chip 140-1 and the fourth substrate pad 159 may also be reduced. As a result, the size of the package substrate 150 may be decreased so that the multi-chip package 100g may have a small size.

In example embodiments, the horizontal length L4 between the 4-2 bonding pad 142-2 and the fourth substrate pad 158 may be substantially equal to the vertical length T4 from the upper surface of the package substrate 150 to the upper surface of the 4-2 semiconductor chip 140-2. Alternatively, the horizontal length L4 between the 4-2 bonding pad 142-2 and the fourth substrate pad 158 may be no more than the vertical length T4 from the upper surface of the package substrate 150 to the upper surface of the 4-2 semiconductor chip 140-2. In some embodiments, the horizontal length L4 may be less than the vertical length T4.

According to example embodiments, the substrate wire may electrically connect the substrate pad of the package substrate with the bonding pad of any one among the semiconductor chips except for the lowermost semiconductor chip. Thus, a sufficient wire gap may be secured between the pad wire and the substrate wire to provide the short horizontal length between the lowermost semiconductor chip and the substrate pad. As a result, the multi-chip package may have a small size.

Further, when the at least two groups of the semiconductor chips may be stacked in the opposite directions, the substrate wire may electrically connect the substrate pad of the package substrate with the bonding pad of the any one on an overhang semiconductor chip corresponding to the lowermost semiconductor chip. Thus, the semiconductor chip over the lowermost semiconductor chip may be electrically connected with the substrate pad of the package substrate via the substrate wire. Although the short horizontal length may be set between the overhang semiconductor chip and the substrate pad, the substrate wire may be accurately bonded to the substrate pad. As a result, the horizontal length between the overhang semiconductor chip and the substrate pad may be more decreased so that the size of the multi-chip package may be more decreased.

In the present application, the letter “G” may be applied to numerical prefixes described above. For example, the 1-1 to 1-4 semiconductor chips in the first group of semiconductor chips 110 may also be referred to the G1-1 to G1-4 semiconductor chips, respectively. Similarly, the 2-1 to 2-4 semiconductor chips, 3-1 to 3-4 semiconductor chips, and 4-1 to 4-4 semiconductor chips may also be referred to as G2-1 to G2-4 semiconductor chips, G3-1 to G3-4 semiconductor chips, and G4-1 to G4-4 semiconductor chips. Similarly, the 1-1 to 1-4 bonding pads, 2-1 to 2-4 bonding pads, 3-1 to 3-4 bonding pads, and 4-1 to 4-4 bonding pads may be referred to as G1-1 to G1-4 bonding pads, G2-1 to G2-4 bonding pads, G3-1 to G3-4 bonding pads, and G4-1 to G4-4 bonding pads. Similarly, the 1-1 to 1-4 pad wires, 2-1 to 2-4 pad wires, 3-1 to 3-4 pad wires, and 4-1 to 4-4 pad wires may be referred to as G1-1 to G1-4 pad wires, G2-1 to G2-4 pad wires, G3-1 to G3-4 pad wires, and G4-1 to G4-4 pad wires.

In the claims, means-plus-function clauses are intended to cover the structures described herein as performing the recited function and also equivalent structures.

The foregoing is illustrative of some example embodiments and is not to be construed as limiting thereof. Although a few example embodiments have been described, those skilled in the art will readily appreciate that many modifications are possible without materially departing from the novel teachings and effects of inventive concepts. Accordingly, all such modifications are intended to be included within the scope of some example embodiments as defined in the claims.

What is claimed is:

1. A multi-chip package comprising:
a package substrate including a first substrate pad and a second substrate pad;
a first group of semiconductor chips including G1-1 to G1-4 semiconductor chips stacked on an upper surface of the package substrate in a steplike shape along a first direction, the first group of semiconductor chips including G1-1 to G1-4 bonding pads on upper surfaces of the G1-1 to G1-4 semiconductor chips, respectively, and
a horizontal length between the first substrate pad and the G1-2 bonding pad being no more than a vertical length between the upper surface of the package substrate and an upper surface of the G1-2 semiconductor chip;
a second group of semiconductor chips including G2-1 to G2-4 semiconductor chips stacked on an upper surface of the first group of the semiconductor chips in a steplike shape along a second direction opposite to the first direction, the second group of semiconductor chips including G2-1 to G2-4 bonding pads on upper surfaces of the G2-1 to G2-4 semiconductor chips, respectively, and
a horizontal length between the second substrate pad and the G2-2 bonding pad being no more than a vertical length between the upper surface of the package substrate and an upper surface of the G2-2 semiconductor chip;
a G1-1 pad wire electrically connecting the G1-1 bonding pad with the G1-2 bonding pad;
a G1-2 pad wire electrically connecting the G1-2 bonding pad with the G1-3 bonding pad;
a G1-3 pad wire electrically connecting the G1-3 bonding pad with the G1-4 bonding pad;
a first substrate wire electrically connecting the G1-2 bonding pad with the first substrate pad;
a G2-1 pad wire electrically connecting the G2-1 bonding pad with the G2-2 bonding pad;
a G2-2 pad wire electrically connecting the G2-2 bonding pad with the G2-3 bonding pad;
a G2-3 pad wire electrically connecting the G2-3 bonding pad with the G2-4 bonding pad;
a second substrate wire electrically connecting the G2-2 bonding pad with the second substrate pad; and
a molding member on the upper surface of the package substrate, the molding member covering the first group of semiconductor chips and the second group of the semiconductor chips.

2. The multi-chip package of claim 1, wherein the horizontal length between the first substrate pad and the G1-2 bonding pad is equal to the vertical length between the upper surface of the package substrate and the upper surface of the G1-2 semiconductor chip.

3. The multi-chip package of claim 1, wherein the horizontal length between the second substrate pad and the G2-2 bonding pad is equal to the vertical length between the upper surface of the package substrate and the upper surface of the G2-2 semiconductor chip.

4. The multi-chip package of claim 1, further comprising:
a third group of semiconductor chips including G3-1 to G3-4 semiconductor chips stacked on an upper surface of the second group of semiconductor chips in a steplike shape along the first direction, the third group of semiconductor chips including G3-1 to G3-4 bonding pads on upper surfaces of the G3-1 to G3-4 semiconductor chips, respectively;
a fourth group of semiconductor chips including G4-1 to G4-4 semiconductor chips stacked on an upper surface of the third group of semiconductor chips in a steplike shape along the second direction, the fourth group of semiconductor chips including G4-1 to G4-4 bonding pads on upper surfaces of the G4-1 to G4-4 semiconductor chips, respectively, wherein
the package substrate further includes a third substrate pad and a fourth substrate pad,
the third substrate pad is at a position outside of the first substrate pad, relative to a region of the package substrate between the first substrate pad and the second substrate pad, and electrically connected with the third group of semiconductor chips, and
the fourth substrate pad at a position outside of the second substrate pad, relative to the region of the package substrate between the first substrate pad and the second substrate pad, and electrically connected with the fourth group of semiconductor chips.

5. The multi-chip package of claim 4, further comprising:
a G3-1 pad wire electrically connecting the G3-1 bonding pad with the G3-2 bonding pad;
a G3-2 pad wire electrically connecting the G3-2 bonding pad with the G3-3 bonding pad;
a G3-3 pad wire electrically connecting the G3-3 bonding pad with the G3-4 bonding pad;
a third substrate wire electrically connecting the G3-2 bonding pad with the third substrate pad;
a G4-1 pad wire electrically connecting the G4-1 bonding pad with the G4-2 bonding pad;
a G4-2 pad wire electrically connecting the G4-2 bonding pad with the G4-3 bonding pad;
a G4-3 pad wire electrically connecting the G4-3 bonding pad with the G4-4 bonding pad; and
a fourth substrate wire electrically connecting the G4-2 bonding pad with the fourth substrate pad.

6. A multi-chip package comprising:
a package substrate including a first substrate pad and a second substrate pad;
a first group of semiconductor chips including a plurality of first semiconductor chips stacked on an upper surface of the package substrate in a steplike shape along a first direction, the first group of semiconductor chips including first bonding pads on upper surfaces of the plurality of first semiconductor chips, respectively;
a second group of semiconductor chips including a plurality of second semiconductor chips stacked on an upper surface of the first group of semiconductor chips in a steplike shape along a second direction opposite to the first direction, the second group of semiconductor chips including second bonding pads on upper surfaces of the plurality of second semiconductor chips, respectively;
a first group of pad wires electrically connecting the first bonding pads of the first group of semiconductor chips with each other;
a first substrate wire electrically connecting the first substrate pad with a first bonding pad of the first semiconductor chip secondarily positioned from below among the plurality of first semiconductor chips in the first group;
a second group of pad wires electrically connecting the second bonding pads of the second group of semiconductor chips with each other; and
a second substrate wire electrically connecting the second substrate pad with a second bonding pad of a second semiconductor chip secondarily positioned from below among the plurality of second semiconductor chips in the second group.

7. The multi-chip package of claim 6, wherein a horizontal length between the first substrate pad and the first bonding pad connected to the first substrate wire is no more than a vertical length between the upper surface of the package substrate and the upper surface of the first semiconductor chip connected to the first substrate wire.

8. The multi-chip package of claim 6, wherein a horizontal length between the second substrate pad and the second bonding pad connected to the second substrate wire is no more than a vertical length between the upper surface of the package substrate and the upper surface of the second semiconductor chip connected to the second substrate wire.

9. The multi-chip package of claim 6, further comprising:
a third group of semiconductor chips including a plurality of third semiconductor chips stacked on an upper surface of the second group of semiconductor chips in a steplike shape along the first direction, the third group of semiconductor chips including third bonding pads on upper surfaces of the plurality of third semiconductor chips, respectively;
a third group of pad wires electrically connecting the third bonding pads of the third group of semiconductor chips with each other; and
a third substrate wire, wherein
the package substrate further includes a third substrate pad on the upper surface of the package substrate at a position outside of the first substrate pad, relative to a region of the package substrate between the first substrate pad and the second substrate pad, and
the third substrate wire electrically connects the third substrate pad with a third bonding pad of a third semiconductor chip secondarily positioned from below among the plurality of third semiconductor chips in the third group.

10. The multi-chip package of claim 9, further comprising:
a fourth group of semiconductor chips including a plurality of fourth semiconductor chips stacked on an upper surface of the third group of semiconductor chips in a steplike shape along the second direction, the fourth group of semiconductor chips including fourth bonding pads on upper surfaces of the plurality of fourth semiconductor chips, respectively;
a fourth group of pad wires electrically connecting the fourth bonding pads of the fourth group of semiconductor chips with each other; and
a fourth substrate wire, wherein
the package substrate further includes a fourth substrate pad on the upper surface of the package substrate outside the second substrate pad, relative to the region of the package substrate between the first substrate pad and the second substrate pad, and
the fourth substrate wire electrically connects the fourth substrate pad with a fourth bonding pad of a fourth semiconductor chip secondarily positioned from below among the plurality of fourth semiconductor chips in the fourth group.

11. A multi-chip package comprising:
a package substrate including a first substrate pad and a second substrate pad;
a first group of semiconductor chips including a plurality of first semiconductor chips stacked on an upper surface of the package substrate in a steplike shape along a first direction, the first group of semiconductor chips including first bonding pads on upper surfaces of the plurality of first semiconductor chips, respectively;
a first group of pad wires electrically connecting the first bonding pads of the first group of semiconductor chips with each other; and
a first substrate wire electrically connecting the first substrate pad with a first bonding pad of any one among the plurality of first semiconductor chips except for a lowermost first semiconductor chip among the plurality of first semiconductor chips in the first group.

12. The multi-chip package of claim 11, wherein the first substrate wire is connected to the first bonding pad of the first semiconductor chip secondarily positioned from below among the plurality of first semiconductor chips in the first group.

13. The multi-chip package of claim 12, wherein a horizontal length between the first substrate pad and the first bonding pad connected to the first substrate wire is no more than a vertical length between the upper surface of the package substrate and the upper surface of the first semiconductor chip connected to the first substrate wire.

14. The multi-chip package of claim 11, further comprising:
a second group of semiconductor chips including a plurality of second semiconductor chips stacked on an upper surface of the first group of semiconductor chips in a steplike shape along a second direction opposite to the first direction, the plurality of second semiconductor chips including second bonding pads on upper surfaces of the plurality of second semiconductor chips, respectively;
a second group of pad wires electrically connecting the second bonding pads of the second group of semiconductor chips with each other; and
a second substrate wire electrically connecting the second substrate pad with a second bonding pad of any one among the plurality of second semiconductor chips except for a lowermost second semiconductor chip among the plurality of second semiconductor chips.

15. The multi-chip package of claim 14, wherein the second substrate wire is connected to the second bonding pad of the second semiconductor chip secondarily positioned from below among the plurality of second semiconductor chips in the second group.

16. The multi-chip package of claim 15, wherein
a horizontal length between the second substrate pad and the second bonding pad connected to the second substrate wire is no more than a vertical length between the upper surface of the package substrate and the upper surface of the second semiconductor chip connected to the first substrate wire.

17. The multi-chip package of claim 14, further comprising:
a third substrate pad on the upper surface of the package substrate at a position outside of the first substrate pad, relative to a region of the package substrate between the first substrate pad and the second substrate pad;
a third group of semiconductor chips including a plurality of third semiconductor chips stacked on an upper surface of the second group of semiconductor chips in a steplike shape along the first direction, the third group of semiconductor chips including third bonding pads on upper surfaces of the plurality of third semiconductor chips, respectively;
a third group of pad wires electrically connecting the third bonding pads of the third group of semiconductor chips with each other; and
a third substrate wire electrically connecting the third substrate pad with a third bonding pad of any one among the plurality of third semiconductor chips except for a lowermost third semiconductor chip among the plurality of third semiconductor chips.

18. The multi-chip package of claim 17, wherein the third substrate wire is connected to the third bonding pad of the third semiconductor chip secondarily positioned from below among the plurality of third semiconductor chips in the third group.

19. The multi-chip package of claim 17, further comprising:
a fourth substrate pad on the upper surface of the package substrate at a position outside of the second substrate pad, relative to the region of the package substrate between the first substrate pad and the second substrate pad;
a fourth group of semiconductor chips including a plurality of fourth semiconductor chips stacked on an upper surface of the third group of semiconductor chips in a steplike shape along the second direction, the fourth group of semiconductor chips including fourth bonding pads on upper surfaces of the plurality of fourth semiconductor chips, respectively;
a fourth group of pad wires electrically connecting the fourth bonding pads of the fourth group of semiconductor chips with each other; and
a fourth substrate wire electrically connecting the fourth substrate pad with a fourth bonding pad of any one among the plurality of fourth semiconductor chips except for a lowermost fourth semiconductor chip among the plurality of fourth semiconductor chips.

20. The multi-chip package of claim 19, wherein the fourth substrate wire is connected to the fourth bonding pad of the fourth semiconductor chip secondarily positioned from below among the plurality of fourth semiconductor chips.
